(19) United States
(12) Patent Application Publication
(10) Pub. No.: US 2026/0287639 A1
(43) Pub. Date: Sep. 24, 2026

(54) GATE CHARGE DE-EMBEDDING

(71) Applicant: X-FAB France SAS, Corbeil-Essonnes (FR)

(72) Inventors: Joao Roberto Raposo De Oliveira Martins, Paris (FR); Rachid Hamani, Corbeil-Essonnes (FR); Vincent Quenette, Koeur-La-Petite (FR); Joerg Geßner, Erfurt (DE)

(21) Appl. No.: 19/385,708

(22) Filed: Nov. 11, 2025

(30) Foreign Application Priority Data
Mar. 19, 2025 (FR) 2502818
Apr. 16, 2025 (GB) 2505718.3

(51) Int. Cl. G01R 31/26

(52) U.S. Cl. CPC G01R 31/2621; G01R 31/2644

(57) ABSTRACT

A method of measuring a gate charge of a semiconductor transistor comprising a source, a drain and a gate, the method comprises:
determining a total gate to source capacitance (Cgstot);
determining a drain to system capacitance (Cdsys), wherein the system comprises a probe for contacting the transistor;
determining a total gate to drain capacitance (Cgdtot);
determining a parasitic drain capacitance (Cgdp), using the drain to system capacitance (Cdsys) and the total gate to drain capacitance (Cgdtot);
measuring a gate voltage and a drain voltage over time, while providing a constant gate current (Ig); and
calculating a de-embedded gate charge from the constant gate current, the measured gate voltage, the measured drain voltage, the total gate to source capacitance, and the parasitic drain capacitance.

### CROSS-REFERENCE TO RELATED APPLICATIONS

This application claims the benefit of and priority to French Patent Application No. 2502818, filed on Mar. 19, 2025, under 35 U.S.C. § 119(b). This application further claims the benefit of and priority to British Patent Application No. 2505718.3, filed on Apr. 16, 2026, under 35 U.S.C. § 119(b). The entire contents of the foregoing applications are incorporated herein by reference in their entireties.

### TECHNICAL FIELD

The invention relates to improved gate charge de-embedding.

### BACKGROUND

Gate charge parameters (Qg, Qgs, Qgd) are key figures of merits (FOMs) of power MOSFET devices. These parameters can be critical for switching performance and efficiency of MOSFETs and similar devices, especially for power electronic applications (e.g. HVMOS, IGBT, SiC, GaN).

In modern integrated power electronics, parasitic elements introduced by test equipment and measurements techniques need to be handled more carefully compared to discrete devices/older technological nodes. Therefore, accurate gate charge measurements are important to build and verify power and high voltage device models suitable for electrification and energy efficiency designs.

A few methods have been proposed for measuring these parameters, most of them applying or measuring the current at the gate as given by B. J. Baliga, Fundamentals of power semiconductor devices, New York, NY: Springer, 2008.

V. Krishnamurthy, A. Gyure, and P. Francis, “Simple gate charge (Qg) measurement technique for on-wafer statistical monitoring and modeling of power semiconductor devices,” in 2012 IEEE International Conference on Microelectronic Test Structures. San Diego, CA, USA: IEEE, March 2012, pp. 98-100 (V. Krishnamurthy et. al.) describes a procedure for estimating only the total gate charge (Qg), which is developed by using just capacitance (CV) measurements.

J. JESD24-2, “Jesd24-2 gate charge test method,” 2002 (JESD24-2) provides a standard method using a forced gate current with a current limited voltage source between drain and source without any calibration performed.

Tektronix, “Measuring gate charge of a device with acs soft-ware,” 2022 (Tektronix) pro-poses an automated solution from JESD24-2 for on-wafer gate charge measurements, where a calibration is done for excluding cable charging between the gate and source terminals and inherited capacitances of the measurement equipment.

### SUMMARY

Aspects of the invention provide a method of measuring the gate charge of a transistor and of determining one or more gate charge parameters as set out in the appended claims.

Embodiments of the invention are described below with reference to the accompanying drawings.

### BRIEF DESCRIPTION OF DRAWINGS

FIG. 1 shows a schematic diagram of a three terminal MOSFET device;

FIG. 2 shows an equivalent circuit diagram of a device under test (DUT) and test system;

FIG. 3 shows a graph of measured parasitic gate to source voltage Vgsp;

FIG. 4 shows a circuit diagram of a measurement setup for measuring the gate charge of a transistor;

FIG. 5 shows a schematic graph of a gate charge measurement;

FIG. 6 shows a graph with measurement data for the gate charge Q;

FIG. 7 shows a similar graph comparing the results from a conventional de-embedding method with those from the de-embedding method described herein; and

FIG. 8 shows a flow diagram illustrating some steps of a method of measuring the gate charge of a transistor.

### DETAILED DESCRIPTION

One method of measuring the gate charge of a MOSFET is by forcing a gate current while the gate to source voltage is measured as a function of time. From the resulting gate voltage waveform, the gate-source charge (Q_{gs}), gate-drain charge (Q_{gd}), and gate charge (Q_{g}) can be obtained.

In the Gate Charge Method, a fixed test current (I_{g}) is forced into the gate of a MOS transistor and the measured gate source voltage (V_{gs}) is plotted against the charge flowing into the gate. A fixed voltage bias is applied to the drain terminal.

The gate charge (Qg) is derived from the forced gate current over time, (Ig). The gate-source charge (Qgs) is the charge required, to reach the beginning of the plateau region where the voltage (Vgs) is almost constant. The plateau (or Miller plateau) voltage (Vgspl) is defined, according JESD24-2 standard, as the gate-source voltage when dVgs/dt is at a minimum. The voltage plateau occurs when the transistor current is the same as the current limit at the drain terminal. The gate charge required to complete this switching, that is the charge needed to switch the device from the beginning of the plateau region to the end, is defined as the gate-drain charge (Qgd) and is known as the Miller charge. The gate charge (Qg) is the charge from the origin to the point where the gate-source voltage (Vgs) is equal to a specified maximum.

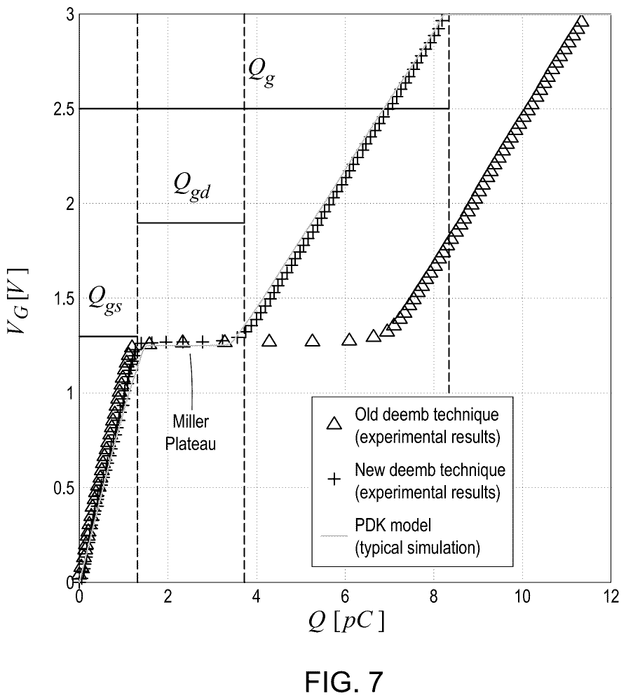

Described herein is a new de-embedding technique for improved on-wafer gate charge measurements. Embodiments can allow for correct de-embedding of all relevant parasitic capacitances on a gate charge measurement by considering the capacitances between gate and source and between gate and drain. The proposed technique has been validated on a 180 nm node 40V HVMOS device and compared to state-of-the-art methods (see FIG. 7 and Table 1). This developed method aims to accurately characterize the transient behaviour at high voltages, additional to the typical CV measurements capability, and can thus help accurate modelling for high-speed switching and high-power devices.

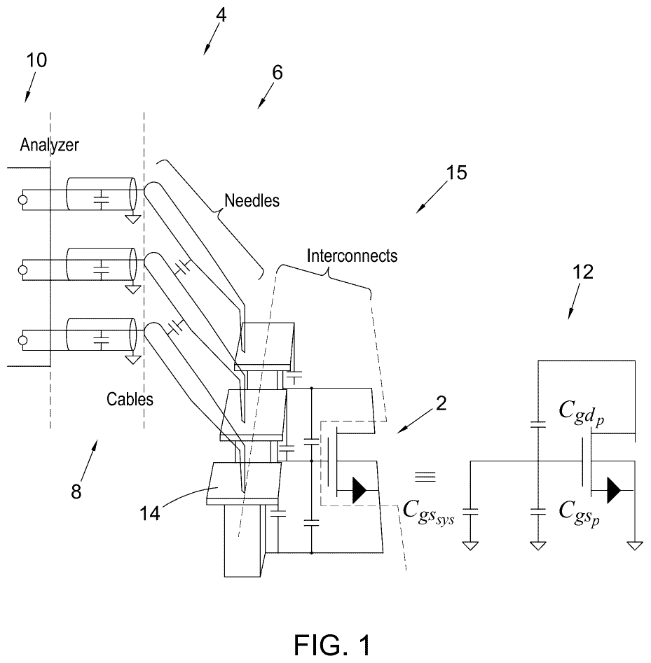

FIG. 1 shows a schematic diagram of a three terminal MOSFET device 2 and a test system 4 comprising three probes 6 (also referred to as needles), cables 8 and an analyser 10 (e.g. a waveform generator) and their circuit representation 12. The probes 6 are connected to the analyser 10 at one end for both measuring voltage or current and also for generating waveforms (current or voltage). The probes 6 are arranged to contact the device under test (DUT), being the MOSFET device 2. Each probe 6 is arranged to contact one of the source, drain and gate of the transistor 2 via connection pads 14 and other interconnects 15 (e.g. vias and metal layers of the wafer comprising the transistor 2). Typically the wafer comprises exposed connection pads 14 for contacting with the probes 6 and a plurality vias and metal layers between the connection pads 14 and the terminals of the MOSFET.

Conventional de-embedding methods may be able to remove the influence of the test system 4 from the measured gate charge. Depending on the cabling and connections of the test system 4, the system capacitance can be in the single picofarads to hundreds of picofarads range. However, the measured gate charge can then still be affected by parasitic capacitances in the wafer. In particular, parasitic capacitances of the interconnects 15 and connection pads 14.

To measure/determine the intrinsic gate charge, also referred to herein as the de-embedded gate charge, the parasitic capacitances between gate and source and between gate and drain are determined and then de-embedded from the gate charge. Preferred embodiments of determining the parasitic capacitances and of de-embedding are described below.

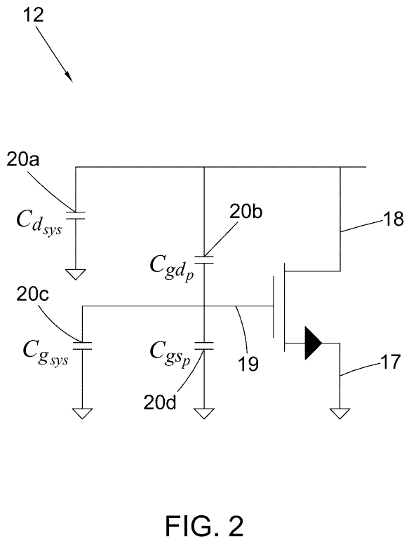

FIG. 2 shows an equivalent circuit diagram 12 of the DUT 2 (transistor) and test system. The same reference numerals have been used in different figures to refer to similar or equivalent features to aid understanding and are not intended to limit the illustrated embodiments. The transistor comprises a source 17, drain 18 and gate 19. Four capacitors 20a-d are shown representing the capacitances in the system. Cdsys 20a is the capacitance of the test system between the drain and ground. Cgdp 20b is the parasitic drain to gate capacitance. Cgsys 20c is the capacitance of the test system between the gate and ground. Cgsp 20d is the parasitic gate to source capacitance.

The total capacitances of the drain and source are then given by Cgdtot=Cdsys+Cgdp and Cgstot=Cgsys+Cgsp respectively.

The capacitances between gate and source and between gate and drain which come from either the system capacitance Cgsys or from the interconnects and connect pads (Cgsp, Cgdp) should be also considered. Their presence will add parasitic charges to the device charge (Q(t)) as follows:

$$\frac{dQ ( t )}{dt} = {I}_{G} + \frac{{dQ}_{{gs}_{tot}} ( t )}{dt} + \frac{{dQ}_{{gd}_{tot}} ( t )}{dt} \qquad ( 1 )$$

$${Q}_{{gd}_{p}} = {C}_{{gd}_{p}} \cdot {V}_{{gd}_{p}} ( t ) = {C}_{{gd}_{p}} \cdot ( {V}_{D} ( t ) - {V}_{G} ( t ) ) \qquad ( 2 )$$

$${Q}_{{gs}_{tot}} = {C}_{{sp}_{tot}} \cdot {V}_{G} ( t ) \qquad ( 3 )$$

where I_{G} is the input current on the gate charge, V_{G} and V_{D} are the gate to ground voltage and drain to ground voltage, respectively.

To quantify the interconnect parasitics, an open structure is provided. For example, the open structure can be made by removing the contact from the DUT. A current is forced on the gate (in the High pin) and the voltage is measured over time on the same pin while the Low pin is connected to the ground. The capacitance between both pins is simply calculated by the slope of the voltage waveform (C=(dV(t)/dt)⁻¹)).

The characterization of the parasitic network can be performed as follows:

First, the capacitance of the open test structure between gate and source (Cgstot=Cgsys+Cgsp) is measured.

Second, the capacitance of the needles on the air between gate and drain is measured.

Finally, the open test structure is measured between gate and drain to obtain the Cgdp capacitance by excluding the capacitance of the needles on-air.

Once the different capacitances are measured, the de-embedded charge can be calculated using equation 1 and the parasitics charges from equations 2 and 3. In particular, the de-embedded gate charge may be calculated from the measured gate voltage (Vg), the measured drain voltage (Vd), the total gate to source capacitance (Cgstot), and the parasitic drain capacitance (Cgdp). Preferably, the parasitic source capacitance is also determined (e.g. by Cgsp=Cgstot−Cgsys) in order to characterise the parasitic network and/or to validate the measurement results.

The de-embedded gate charge can be calculated from the following equation:

$$\frac{{dQ}_{deembeded} ( t )}{dt} = {I}_{G} - {C}_{{gs}_{tot}} \frac{d}{dt} {V}_{G} ( t ) - {C}_{{gd}_{p}} \frac{d}{dt} ( {V}_{D} ( t ) - {V}_{G} ( t ) )$$

This equation can be numerically solved and integrated over time to provide the gate charge at a particular time t or gate voltage Vg(t).

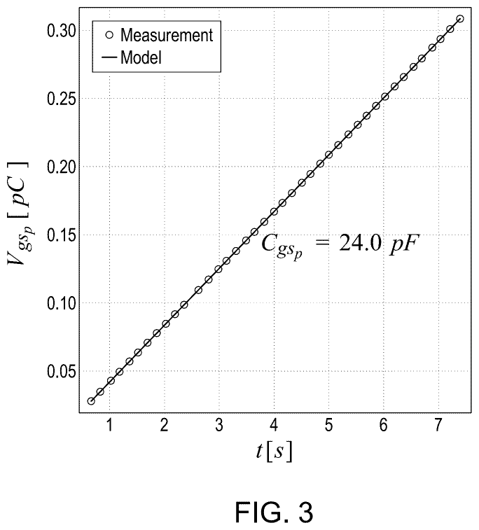

FIG. 3 shows a graph of measured parasitic gate to source voltage Vgsp against time with a constant gate current input on a DUT 2 with an open circuit (drain left floating). The parasitic capacitance between gate and source (Cgsp) from the interconnects 15 in the wafer of the DUT 2 is given by the inverse gradient. The results are aligned with model results shown by the straight line going through the measurement points.

In an embodiment, to determine the parasitic source capacitance, the DUT 2 is left open (drain floating) and the source grounded. A constant current Ig is provided to the gate terminal. For example, an analyser and waveform generator may provide a constant current for a predetermined time period (e.g. a top hat waveform), and the gate voltage between gate and source is measured for the period when the current is constant. T=0 may be set at the time when the current switches on (at the leading edge of the waveform). While the gate current is on, charge builds up on the gate and the gate to source voltage increases. Since the test structure is open, no current flows through the drain, and so there is no voltage plateau.

The voltage contribution from the test system Vgssys (the probe, cables and analyser) is subtracted from the total gate voltage thus measured Vgstot to determine the voltage contribution Vgsp from the parasitic capacitances of the interconnects. The voltage contribution from the test system (due to parasitic capacitances of the probe and cables) can be determined by measuring the gate voltage between gate and source (source grounded) with the probe on air.

A straight line fit to the gate voltage as a function of time can then be used, wherein the capacitance is given by the inverse gradient of the straight line. In other embodiments, the total gate to source capacitance Cgstot can be determined first from a straight line fit to the measured data (Vgstot vs time), and the system capacitance Cgsys subtracted therefrom to determine the parasitic source capacitance Cgsp.

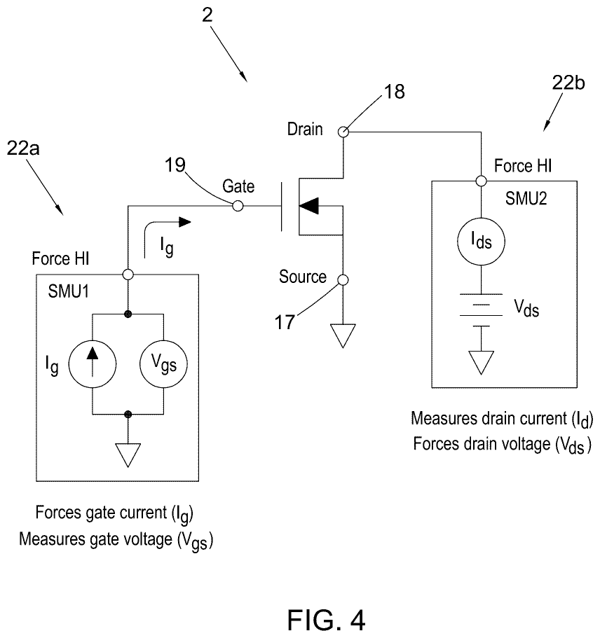

FIG. 4 shows a circuit diagram of a measurement setup for measuring the gate charge of a transistor 2. The setup comprises two source measure units (SMUs), SMU1 22a and SMU2 22b, connected to the gate 19 and drain 18 respectively (e.g. via probes/needles), while the source 17 is grounded. SMU1 22a provides a constant current Ig to the gate, while also measuring the gate voltage Vgs. The second SMU 22b provides a bias voltage to the drain Vds and measures the drain current Id. SMU2 is configured to provide a constant bias voltage Vds with current compliance (I_{DMAX}). The constant drain voltage can also be referred to as the off-state drain voltage, as it is the voltage at the drain 18 when the transistor is off and there is no current flowing through the drain. Once the drain to source current from the transistor reaches Idmax, the drain voltage drops to allow a constant current flow.

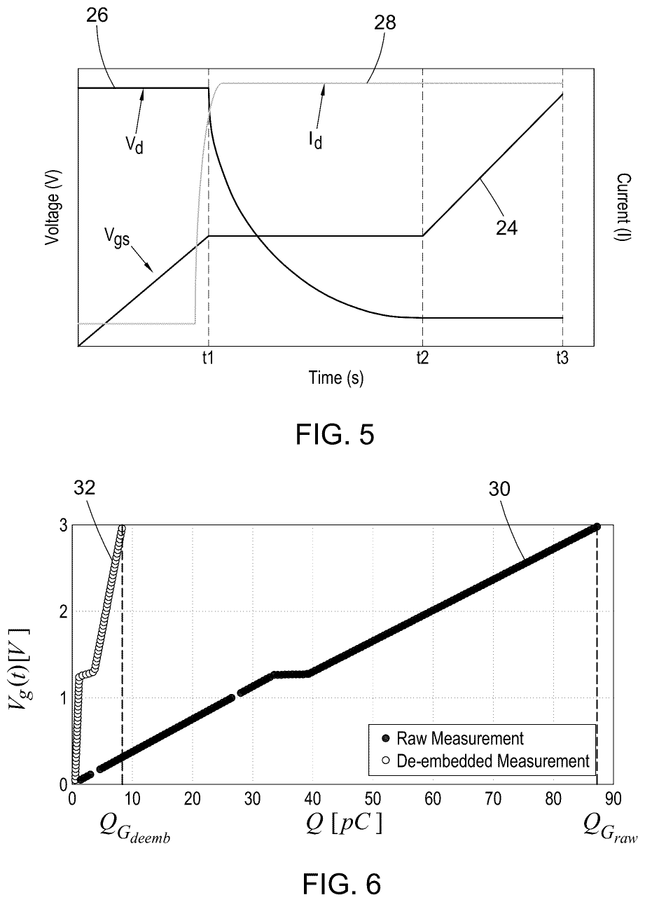

FIG. 5 shows a schematic graph of a gate charge measurement. The measurement may be made using the setup illustrated in FIG. 1 or FIG. 4 for example. The gate voltage Vgs 24, the drain voltage Vd 26 and the drain current Id 28 are plotted against time. As current Ig is forced to the gate, Vgs 24 increases until it reaches a threshold voltage. At this point, the drain current Id 28 begins to flow. When Cgs is charged up at time t1, Id 28 stays substantially constant and the drain voltage Vd 26 decreases. Vgs 24 remains constant until it reaches the end of the plateau at time t2. Once Cgd is charged, at time t2, the gate to source voltage Vgs 24 starts to increase again until it reaches a maximum gate voltage.

FIG. 6 shows a graph with measurement data for the gate charge Q. The graph shows both the raw measurement data 30 of the gate voltage as a function of gate charge Q and the de-embedded gate voltage 32. As can be seen, the intrinsic (de-embedded) gate charge increases more slowly with gate voltage, and gate voltage increase more rapidly with the intrinsic gate charge.

FIG. 7 shows a similar graph comparing the results from a conventional de-embedding method with those from the de-embedding method described herein as well as simulated results from a PDK model. The measurements were made on a 40 V N-type HVMOS (W=100 m, L=0.4 m, NF=10) from X-FAB 180 nm BCD on SOI process (1.8 V for standard devices). The gate charge was measured using a Keithley 4200 SCS analyzer by applying a 5 pA gate current and a drain voltage of 3 V with current compliance of 100 μA. The gate charge results were de-embedded with the new technique and the different FOMs are calculated.

As can be seen, the proposed measurement method provides results that match the simulated results better than those of the conventional method. From the graph, the gate charge parameters, Qgs, Qgd and Qg can be determined.

In the first part of the measurements, before the Miller Plateau, both measurement techniques present similar results, due to a low metallization capacitance compared to the system capacitance (Cgsp/Cgsys=5%). The same observation for the slope after the miller plateau is noted. The Miller Plateau itself is longer for the old technique, indicating a bigger measured Cgd capacitance. These observations confirm that the old de-embedding technique is not sufficient to accurately exclude the parasitics on both gate to source and gate to drain capacitances.

To compare the total gate charge, one can use the technique proposed in V. Krishnamurthy et. al. that uses the measured total gate capacitance (Cgdsb) and the gate to drain capacitance (Cgd) to estimate the Qg for a given transistor. The capacitance integrals were performed using trapezoidal rule and total gate charge at Vg=Vd=3 V of 8.06 pC is calculated (see Table 1). The total gate charge using a method as described herein gives 8.33 pC and this is in accordance with the CV based method with a relative error of about 3%. As it can be seen from Table 1, the proposed method is also providing gate to source charge (Qgs) and gate to drain charge (Qgd), which are also a relevant FOMs for switching performances of power devices. Both results were compared to a PDK model, where a schematic level test bench replicating the technique proposed in JESD24-2 was simulated using Spectre (Cadence, “Spectre® Circuit Simulator Reference,” 2020). The model used for this validation is extracted from a full DC, CV (de-embedded), Pulsed IV, and Reverse Recovery measurements. Not only the simulated total gate charge (Qg=8.22 pC) but also the Qgd and Qgs are comparable to the measured results using the method described herein.

TABLE 1
comparison between different gate charge
FOMs obtained from different methods

| | | | Measured | Measured |
|---|---|---|---|---|
| | Calculated | Simulated | using de- | using old de- |
| | using V. | using PDK | embedding | embedding |
| | Krishnamurthy | model (Typical ± | described | method from |
| | et. al. | 3 sigma) | herein | Tektronix |
| Qg | 8.06 | 8.22 ± 1.52 | 8.33 | 12.99 |
| Qgd | NA | 2.03 ± 1.07 | 2.4 | 6.37 |
| Qgs | NA | 1.41 ± 0.53 | 1.32 | 0.71 |

The measured Qgd using the new method is higher than the simulated model. The difference is attributed to the fact that the measurement is performed on a single die and the measured silicon is around 1 sigma of typical value. Due to the complex parasitic network, the measurement procedure and the de-embedding may require several steps as described in embodiments herein.

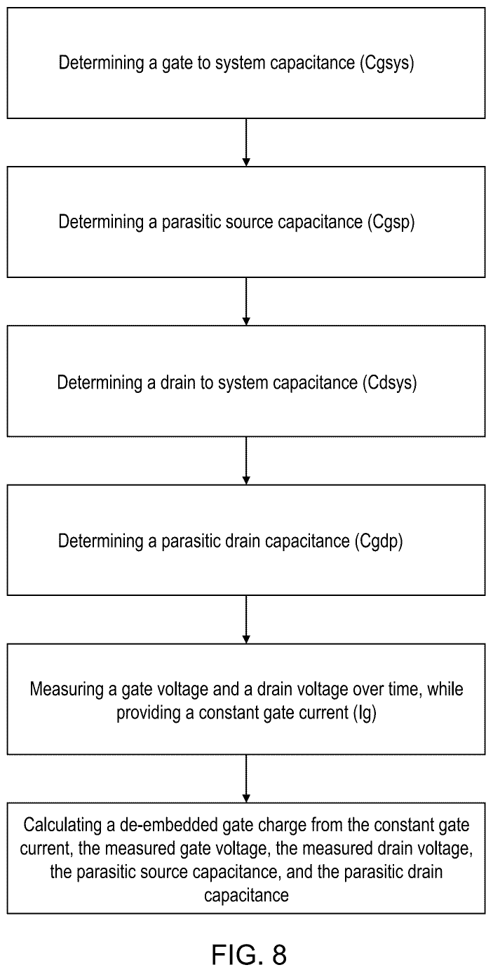

FIG. 8 shows a flow diagram illustrating some steps of a method of measuring the gate charge of a transistor. The method comprises determining a gate to system capacitance (Cgsys) (step S1). The system capacitance can be determined by taking a measurement with the test probe on air. The method further comprises determining a parasitic source capacitance (Cgsp) (step S2). This is the parasitic capacitance from the interconnects of the wafer (e.g. comprising the source connection pad) between the gate and source. The parasitic source capacitance can be determined by subtracting the system capacitance from the total gate to source capacitance. The method further comprises determining a drain to system capacitance (step S3) and a parasitic drain capacitance (step S4). The method then comprises measuring the gate and drain voltages while supplying a constant gate current (Ig) (step S5) and calculating the de-embedded gate charge from the gate current, the measured gate voltage, the measured drain voltage, the parasitic source capacitance and the parasitic drain capacitance.

The method may be carried out using the test setup described in relation to FIG. 1 above.

In general, embodiments described herein provide a method of measuring a gate charge of a semiconductor transistor comprising a source, a drain and a gate. The method comprises:
determining a total gate to source capacitance (Cgstot);
determining a drain to system capacitance (Cdsys), wherein the system comprises a probe for contacting the transistor;
determining a parasitic drain capacitance (Cgdp), using the total drain to gate capacitance (Cgdtot) and the drain to system capacitance (Cdsys);
measuring a gate voltage and a drain voltage over time, while providing a constant gate current (Ig); and
calculating a de-embedded gate charge from the constant gate current, the measured gate voltage, the measured drain voltage, the total gate to source capacitance, and the parasitic drain capacitance.

The constant gate current may be within a range of 1 pA to 10 pA, and may be configured to remain constant for a period of at least 10 s. Measuring the gate voltage may be performed within this period and may be configured to coincide with this period.

The gate voltage and the drain voltage are measured simultaneously, for example using two separate source measurement units (SMUs) as the transistor switches on. That is, the measurement over time starts when the transistor is in an off state and continues to take continue as the gate charge builds up due to the gate current until the transistor is in an on state and a drain current can flow. Each SMU may comprise a probe with one or more probe ends for contacting contact pads on a semiconductor wafer comprising the transistor.

The transistor may be, and the method may be particularly suitable for, a MOSFET. In particular, the transistor may be a high voltage (HV) MOSFET. The transistor may be referred to as the “device under test” DUT.

The test unit may be an analyser and wave generator, which can both take voltage and current measurements and simultaneously provide voltage and current inputs. For example, the test system may be configured to provide a constant current pulse through a probe and simultaneously measure the voltage on that probe.

The method may comprise two measurements with the probes of the test system on air (not connected to the DUT) to determine the gate to system capacitance and the drain to system capacitance. The method may comprise two further measurements of the gate voltage with an open test structure to determine the parasitic source capacitance and the parasitic drain capacitance.

The total gate to drain capacitance can be defined as the total capacitance between gate and drain that will be present for the subsequent measurement of gate voltage and drain voltage used to calculate the gate charge. The drain to system capacitance can be defined as the capacitance in the test system (e.g. comprising probes and cables) between the drain probe (or probe end) and ground. The parasitic drain capacitance can be defined as the capacitance between gate and drain within the DUT itself (independent of the test system). The parasitic drain capacitance may arise from capacitances between vias, electric contact pads and other interconnects on/in the wafer between the gate and drain.

The total gate to source capacitance can be defined as the total capacitance between gate and source that will be present for the subsequent measurement of gate voltage and drain voltage used to calculate the gate charge. The method may further comprise determining a gate to system capacitance (Cgsys), and determining a parasitic source capacitance (Cgsp), using the gate to system capacitance (Cgsys). The gate to system capacitance can be defined as the capacitance in the test system (e.g. comprising probes and cables) between the gate probe (or probe end) and the source probe or between the gate probe and ground. The parasitic source capacitance can be defined as the capacitance between gate and source within the DUT itself (independent of the test system). The parasitic source capacitance may arise from capacitances between vias, electric contact pads and other interconnects on/in the wafer between the gate and source.

Determining the gate to system capacitance (Cgsys) may comprise:
grounding a source of the transistor;
disconnecting a drain of the transistor, so that the drain is floating;
providing a constant gate current (Ig);
while the source is grounded, the drain is floating and the constant gate current is provided, measuring a gate voltage (Vg) of the probe on air between the gate and the source; and
calculating the gate to system capacitance from the measured gate voltage.

When the probe is in the air, there exist a capacitance (air capacitance) between the probe ends that are arranged to contact the gate and the source. This system capacitance can be measured the same way as if the probes were contacting the DUT with the curve Vgs vs time.

Hence, several steps of measuring the gate voltage may be used, with different arrangements of the test system and the transistor connections. For different measurements of the gate voltage where a constant gate current is provided, the same constant value for the current is preferably used. The gate current may also be kept constant for the same period of time in the different measurements. Having the same input current to the gate for different measurements may provide more accurate de-embedding.

Determining the parasitic source capacitance may comprise subtracting the gate to system capacitance from the total gate to source capacitance.

Determining the total gate to source capacitance may comprise:
grounding the source of the transistor;
disconnecting the drain of the transistor, so that the drain is floating;
providing a constant gate current (Ig);
while the source is grounded, the drain is floating and the constant gate current is provided, measuring a gate voltage between the gate and the source; and
calculating the total gate to source capacitance from the measured gate voltage (Vg).

Determining the drain to system capacitance may comprise:
grounding the drain of the transistor;
disconnecting the source of the transistor, so that the source is floating;
providing a constant gate current (IG);
while the drain is grounded, the source is floating and the constant gate current is provided, measuring a gate voltage of the probe on air between the gate and the drain;
calculating the drain system capacitance from the measured gate voltage (Vg).

When the probe is in the air, there exist a capacitance (air capacitance) between the probe ends that are arranged to contact the gate and the drain. This system capacitance can be measured the same way as if the probes were contacting the DUT with the curve Vgs vs time.

Determining the drain parasitic capacitance may comprise subtracting the drain system capacitance from the total gate to drain capacitance.

Determining the total gate to source capacitance may comprise:
grounding the drain of the transistor;
disconnecting the source of the transistor, so that the source is floating; providing a constant gate current (IG);
while the drain is grounded, the source is floating and the constant gate current is provided, measuring a gate voltage between the gate and the drain;
calculating the total gate to drain capacitance from the measured gate voltage (Vg).

While measuring the gate voltage and the drain voltage over time, a constant voltage can be provided to the drain within a limit for a drain current. For example, the drain may be biased with a constant voltage Vd, which starts to drop when the channel opens and a drain current begins to flow.

Hence, in an embodiment, the gate (probe) voltage is measured five separate times with different circuit setups and test system setups. Four measurements are made to determine the system capacitances (due to the test system comprising the probes) and the individual parasitic capacitances between gate and source and between gate. The “final” measurement of the gate voltage and drain voltage is used to calculate the gate charge, which is de-embedded using the capacitances determined from the other four measurements. This measurement of gate voltage (and simultaneously of drain voltage) can be performed last or first or at some other point in the measurement process. When performed first, the measured gate voltage, or the gate charge determined therefrom, can be de-embedded in post processing using the capacitances determined from the subsequent measurements. What this measurement is performed last, then the measurements can be directly and automatically de-embedded in situ. For example, the test system or a processing unit connected to the test system can be configured to take the determined capacitances as input and to use them to automatically calculate and de-embed the gate charge from the measured gate voltage.

Calculating a de-embedded gate charge may comprise the following steps:
calculating a gate charge current; and
integrating the gate charge current over time.

Calculating the gate charge current may comprise numerically solving the following equation:

$$\frac{{dQ}_{deembeded} ( t )}{dt} = {I}_{G} - {C}_{{gs}_{tot}} \frac{d}{dt} {V}_{G} ( t ) - {C}_{{gd}_{p}} \frac{d}{dt} ( {V}_{D} ( t ) - {V}_{G} ( t ) ) ,$$

wherein Q_{deembedded}(t) is the gate charge as a function of time, I_{G} is the constant gate current, C_{gstot} is the total gate to source capacitance, V_{G}(t) is the measured gate voltage as a function of time, C_{gdps} is the parasitic drain capacitance, and V_{D}(t) is the measured drain voltage as a function of time.

Further embodiments described herein provide a method of determining a gate charge parameter. The method comprises:
measuring the gate charge according to any one of the preceding claims;
providing the measured gate voltage as a function of the gate charge;
determining the gate charge parameter from the gate charge at one or more gate voltage values.

The method may comprise determining one or more further gate charge parameters from the measured gate voltage and the gate charge. The gate charge parameters comprise at least one of Qg, Qgs and Qgd.

While specific embodiments have been described above, it will be apparent to one skilled in the art that modifications may be made to the embodiments as described without departing from the scope of the claims set out below. Each feature disclosed or illustrated in the present specification may be incorporated in the embodiments, whether alone or in any appropriate combination with any other feature disclosed or illustrated herein.

1. A method of measuring a gate charge of a semiconductor transistor comprising a source, a drain and a gate, the method comprising:
determining a total gate to source capacitance (Cgstot);
determining a drain to system capacitance (Cdsys), wherein the system comprises a probe for contacting the transistor;
determining a total gate to drain capacitance (Cgdtot);
determining a parasitic drain capacitance (Cgdp), using the drain to system capacitance (Cdsys) and the total gate to drain capacitance (Cgdtot);
measuring a gate voltage and a drain voltage over time, while providing a constant gate current (Ig); and
calculating a de-embedded gate charge from the constant gate current, the measured gate voltage, the measured drain voltage, the total gate to source capacitance, and the parasitic drain capacitance.

2. A method according to claim 1, wherein the determining the total gate to source capacitance comprises:
grounding the source of the transistor;
disconnecting the drain of the transistor, so that the drain is floating;
providing a constant gate current (Ig);
while the source is grounded, the drain is floating and the constant gate current is provided, measuring a gate voltage between the gate and the source;
calculating the total gate to source capacitance from the measured gate voltage (Vg).

3. A method according to claim 1, further comprising determining a gate to system capacitance (Cgsys), wherein the determining the gate to system capacitance comprises:
grounding a source of the transistor;
disconnecting a drain of the transistor, so that the drain is floating;
providing a constant gate current (Ig);
while the source is grounded, the drain is floating and the constant gate current is provided, measuring a gate voltage (Vg) of the probe on air between the gate and the source; and
calculating the gate to system capacitance from the measured gate voltage.

4. A method according to claim 3, further comprising determining a parasitic source capacitance by subtracting the gate to system capacitance from the total gate to source capacitance.

5. A method according to claim 1, wherein determining the drain to system capacitance comprises:
grounding the drain of the transistor;
disconnecting the source of the transistor, so that the source is floating;
providing a constant gate current (Ig);
while the drain is grounded, the source is floating and the constant gate current is provided, measuring a gate voltage of the probe on air between the gate and the drain;
calculating the drain system capacitance from the measured gate voltage (Vg).

6. A method according to claim 1, wherein determining the drain parasitic capacitance comprises subtracting the drain system capacitance from the total gate to drain capacitance.

7. A method according to claim 6, wherein determining the total gate to source capacitance comprises:
grounding the drain of the transistor;
disconnecting the source of the transistor, so that the source is floating;
providing a constant gate current (Ig);
while the drain is grounded, the source is floating and the constant gate current is provided, measuring a gate voltage between the gate and the drain; and
calculating the total gate to drain capacitance from the measured gate voltage (Vg).

8. A method according to claim 1, further comprising, while measuring the gate voltage and the drain voltage over time, providing a constant voltage to the drain within a limit for a drain current.

9. A method according to claim 1, wherein calculating a de-embedded gate charge comprises:
calculating a gate charge current; and
integrating the gate charge current over time.

10. A method according to claim 9, wherein calculating the gate charge current comprises numerically solving the following equation:
$$\frac{{dQ}_{deembeded} ( t )}{dt} = {I}_{G} - {C}_{{gs}_{tot}} \frac{d}{dt} {V}_{G} ( t ) - {C}_{{gd}_{p}} \frac{d}{dt} ( {V}_{D} ( t ) - {V}_{G} ( t ) ) ,$$
wherein Qdeembedded(t) is the gate charge as a function of time, IG is the constant gate current, Cgstot is the total gate to source capacitance, VG(t) is the measured gate voltage as a function of time, Cgdps is the parasitic drain capacitance, and VD(t) is the measured drain voltage as a function of time.

11. A method of determining a gate charge parameter, the method comprising:
measuring the gate charge according to claim 1;
providing the measured gate voltage as a function of the gate charge;
determining the gate charge parameter from the gate charge at one or more gate voltage values.

12. A method according to claim 11, further comprising determining one or more further gate charge parameters from the measured gate voltage and the gate charge.

13. A method according to claim 12, wherein the gate charge parameters comprise at least one of Qg, Qgs and Qgd.
